(19) United States
(12) Patent Application Publication
(10) Pub. No.: US 2026/0202445 A1
(43) Pub. Date: Jul. 16, 2026

(54) SENSOR DEVICE, CURRENT SENSING SYSTEM AND MANUFACTURING METHOD

(71) Applicant: Infineon Technologies Austria AG, Villach (AT)

(72) Inventors: Edward Fürgut, Dasing (DE); Rainer Schaller, Aichen, Memmenhausen (DE)

(21) Appl. No.: 19/446,309

(22) Filed: Jan. 12, 2026

(30) Foreign Application Priority Data
Jan. 13, 2025 (DE) 102025100853.1

(51) Int. Cl. G01R 15/20; G01R 3/00; G01R 19/00

(52) U.S. Cl. CPC G01R 15/202; G01R 3/00; G01R 15/205; G01R 19/0092

(57) ABSTRACT

A sensor device is configured to be attached to a submount, the submount forming a main current path. The sensor device includes: a first connector to connect to the main current path; a second connector to connect to the main current path; an electrical bypass element arranged between and coupled to the first connector and the second connector, the bypass element forming a bypass current path; an insulator body receiving the bypass element; and a sense circuit including at least one magnetic field sensitive element configured to sense a magnetic field induced by a bypass current through the bypass element.

### TECHNICAL FIELD

The present disclosure relates to a sensor device configured to be attached to a submount, the submount forming a main current path. The disclosure further relates to a current sensing system comprising the sensor device and to a method of manufacturing a sensor device.

### BACKGROUND

Many applications such as automotive and industrial applications utilize semiconductor packages to accommodate high voltage loads. These packages can include power device such as diodes, IGBTs, MOSFETs, HEMTs etc. These semiconductor packages can be configured as discrete components or may be configured as power converters, half bridge converters, half-wave rectifiers, single and multi-phase full wave rectifiers, voltage regulators, etc. It is desirable to monitor the operational state of the power devices for various reasons. Present solutions, e.g. from US 2024/0170374 A1 or JP 2005 – 121471 A, may involve making unwanted tradeoffs, such as larger package size, decreased accuracy and/or complicated manufacturability.

Accordingly, it is an objective of the present disclosure to at least mitigate these shortcomings.

### SUMMARY

According to a first aspect of the present disclosure, a sensor device of the aforementioned kind comprises a first connector to connect to the main current path, a second connector to connect to the main current path, an electrical bypass element arranged between and coupled to the first connector and the second connector, the bypass element forming a bypass current path. The sensor device comprises an insulator body for receiving the bypass element and a sense circuit comprising at least one magnetic field sensitive element for sensing a magnetic field induced by a bypass current through the bypass element.

The sensor device according to the first aspect may be configured to be separately attachable to a submount. The submount may be any kind of substrate, particularly a leadframe, or any other electrically conductive material in which a current flow is to be measured. The submount forms a main current path, that is, the main current of interest, which is to be determined, by the sensor device.

For example, the submount may be a discrete power device (like a through hole device, a surface mount device, including respective devices with top side cooling and/or bottom side cooling capabilities), a molded module, an intelligent molded module, a frame module, etc.

The sensor device comprises a first connector, that is, a first electrical connection which may be connected to a first location of the main current path. Moreover, the sensor device comprises a second electrical connection, that is a second connector, which may be connected to a second location of the main current path. Between the first connector and the second connector and an electrical bypass element is arranged.

The bypass element is an electrically conductive element which is coupled to the first connector and the second connector. Thereby, the bypass element forms a bypass current path, that is, an alternative route for a part of the main current through the bypass element. The bypass element is arranged substantially parallel to the main current path. A flow direction of the bypass current may be parallel to a flow direction of the main current. As a result, magnetic fields induced by both the bypass current, and the main current are also substantially parallel and interfere constructively above the bypass element.

The sensor device comprises an insulator body in which the bypass element and the first and second connectors may be embedded. The insulator body is configured to receive the bypass element and may also be configured to receive the first connector and the second connector. The insulator body may be of any insulating material, e.g. of a mold compound or the like. Further, the sensor device comprises a sense circuit, wherein the sense circuit may comprise at least one magnetic field sensitive element. The sense circuit may be a pre-manufactured element and may be configured for sensing magnetic fields induced by the bypass current through the bypass element. Moreover, the sense circuit may also be configured to sense the current through the submount, that is, the main current which does not flow through the bypass element.

By providing a sensor device according to the first aspect it is possible to pre-manufacture the sensor device and to place the sensor device at any arbitrary location of the submount. By the bypass current path, that is by the form or shape of the bypass element, it is possible to induce an exactly measurable magnetic field for the sense circuit. In turn, no particularly or specially adapted form or shape of the submount for inducing an exactly measurable magnetic field is required. This results in greater measurement accuracy and is easy to manufacture.

According to an embodiment, the first connector is spaced apart from the second connector along the main current path, wherein the first and second connectors are surface mount terminals. As mentioned, the first connector and second connector may be attached to different locations at the submount. The first connector may be connected to the submount more upstream than the second connector. In this way the first connector and the second connector are located subsequently along the flow direction of the current of the main current path. Both the first connector and the second connector may be configured as surface mount terminals, that is, portions of the connectors which can be brought in electrical contact with the surface of the submount. The surface mount terminals may be part of the connectors or separate parts. If the surface mount terminals are separate parts, they are layer shaped, wherein the layers may be configured as adhesive layers, solder layers or preform layers or any other electrically conductive layers suitable for use in a standard die attach process.

For example, each connector of the first and second connectors comprises a landing pad. That is, the surface mount terminals may be the landing pads or the landing pads may be additional layers at the connectors and/or the surface mount terminals. The landing pads may e.g. be Sn plated for soldering. Optionally conductive gluing is possible.

In an embodiment, the first and the second connectors are connected to the bypass element by interconnect structures through the insulator body. Particularly, the interconnect structures may be vias but may also be any other suitable electrically conductive structure. The interconnect structures may be substantially vertical and connect the connectors/the landing pads to the bypass element. Via structures are particularly advantageous if the insulator body is of a hard, preformed material. In this case the via structures may be manufactured together with the insulator body.

In an embodiment, the insulator body comprises a first main surface and a second main surface opposite the first main surface, wherein the second main surface is facing the submount, particularly wherein the second main surface comprises a first cavity between the first and second connectors, whereby a portion of the second main surface is spaced away from the submount. The first cavity may be a recess in the second main surface. The second main surface may be a lowermost surface of the insulator body and may be adjacent to an upper surface of the submount. However, by the first cavity at least part of the lowermost surface of the insulator body is spaced away from the submount. The recess may be such that the insulator body comprises a stand-off for undermolding, that is a mold compound could flow under at least part of the sensor device in a possible molding step, wherein the sensor device and at least part of the submount are overmolded or encapsulated by a mold compound.

Particularly, the insulator body is one of a mold body, a laminate body or a glass carrier. The dielectric constant of the molded material may be less than three, ɛ ≤ 3, to reduce electrical fields in possible unwanted cavities inside the mold compound.

In an embodiment the first main surface of the insulator body comprises a second cavity in which the sense circuit is arranged. Arranging the sense circuit in the second cavity improves adhesion and reliability of galvanic insulation at a cemented joint.

In an embodiment, the insulator body comprises sense terminals configured to receive and route sense signals from the at least one magnetic field sensitive element. The sense terminals may have no contact to a bottom side of the insulator body. The sense terminals may be part of a half etched leadframe and may have a suitable plating for pursuing wires, wherein the pursuing wires may be single wires to route sense signals away from the insulator body. Also, the sense terminals may be pre-wire-bonded to the magnetic field sensitive elements. This allows for improved manufacturability.

In an embodiment, the sense circuit is attached to a bottom surface of the second cavity by an adhesive, preferably by a non-conductive glue. Thereby, the sense circuit is arranged inside the cavity, that is the sense circuit is at least in part surrounded by the sidewalls of the cavity. The deeper the second cavity is, the longer is the distance from the sense circuit to the nearest electrically conducting element, for example to the upper surface of the submount. By virtue of the second cavity impurities, which may emerge from the process of overmolding the sensor device, have less effects on possible creepage currents from the sensor device to the nearest electrical conductor. Additionally, in case of delamination and hence impurities due to ions, creepage currents are mitigated.

The sensor device of the first aspect of disclosure may be configured to be mountable to a semiconductor device, particularly to a half-bridge arrangement, wherein the submount is an AC current path of a packaged half-bridge arrangement. In an AC current path, it is an advantage to place the sensor device directly at the current path but spaced apart from the current path due to thermal restrictions. As described above, no extra structures at the die pad are necessary.

In an embodiment the sense circuit is embedded in the insulator body and covered by an insulating layer and wherein the bypass element is arranged atop the insulating layer. In this embodiment, the second, lower surface of the sensor device may be directly attached to an upper surface of the submount without the first cavity. The sense circuit may be located at the first surface of the insulator body and may be embedded in the insulator body. The sense circuit may be covered with an insulating layer, which may be an oxide layer, for example. The bypass element may be arranged atop the insulating layer.

That is, the sensor device is attached to the submount, and the sense circuit may be arranged at a surface of the sensing device facing away from the submount, particularly at the first surface.

Particularly, both the first connector and/or and the second connector are formed by a ribbon bond. The ribbon bonds may electrically connect the bypass element to the upper surface of the submount. Thereby, the ribbon bonds may take the function as the first and second connectors and the interconnect structures at the same time.

In all of the previously described embodiments the sensing element may be one of a Hall-element for vertical magnetic field sensing or a magneto-resistive element, XMR, for lateral magnetic field sensing.

According to a second aspect of the present disclosure a current sensing system is provided, the system comprising: a sensor device according any of the previously described embodiments and aspects, a submount, particularly a leadframe, and a second mold body encapsulating at least part of the submount and the sensor device.

In an embodiment of the second aspect of disclosure the current sensing system further comprises a controller configured to receive a sensing signal from the sensing device, and to convert the sensing signal into an overall current value.

In an embodiment an area ratio of a cross section of the bypass element vertical to a direction of the current flow to a cross section of the submount in the current flow direction is at least 0.08.

In an embodiment, the current sensing system comprises further circuitry for monitoring a state of health and/or a state of operation of the system, wherein the further circuitry is arranged at the submount, particularly wherein the further circuitry is configured for one or more of voltage sensing, humidity sensing, mechanical stress sensing, acceleration sensing. The further circuitry is galvanically and hence electrically separated from each other which contributes to increased accuracy.

According to a third aspect of the present disclosure, a method for manufacturing a sensor device is provided, the method comprising: providing a first connector to connect to a main current path; providing a second connector to connect to the main current path; arranging a bypass element between the first connector and the second connector forming a bypass current path parallel to the main current path; embedding at least the bypass element in an insulator body and mounting a sense circuit at a first main surface of the insulator body, the sense circuit comprising at least one magnetic field sensitive element for sensing a magnetic field induced by a bypass current through the bypass element.

In an embodiment the method comprises embedding the first connector and the second connector in the insulator body.

In a further embodiment, the method comprises coating the magnetic field sensitive element with an insulating layer. Further, the arranging comprises covering the insulating layer with a current trace, the current trace forming the bypass element.

In an embodiment, the method comprises forming a frontside interconnect at the sensor device, wherein the forming comprises a plating step, the plating comprising Ag and/or Ni.

In an embodiment, the method comprises, at the mounting step: strip testing of an area of the insulator body where the sense circuit is to be mounted before mounting the sense circuit to the insulator body. Before mounting the sense circuit to the insulator body, a premolding step may be performed. Thereafter, strip testing may be done at the whole area where the sense circuit is to be arranged before mounting the sense circuit. In this way, it is possible to do strip testing before the mounting of the sense circuit and thereby significantly reduce the failure rate due to faulty sense circuits being mounted onto the insulator body.

Moreover, the whole sensor device may be tested before mounting the sensor device to the submount, preferably with a voltage of at least 10 KV. However, lower voltages are also possible, depending on requirements. This contributes to reducing the failure rate because both the sensor device and the submount can be tested individually. Particularly, the testing comprises determining a breakdown voltage of the insulator body and/or calibrating the sensing circuit. As the sensor circuit may be subject to tolerances during the mounting process, a calibration of the circuit may be carried out before mounting the sensor device to the submount. As a result, for example a low-cost submount can be used. As a further result, a “Known Good Sensor Device” is obtained.

Still further, in an embodiment the method comprises mounting the sensing device to a submount, the submount forming a main current path.

### BRIEF DESCRIPTION OF THE DRAWINGS

Exemplary embodiments of the disclosure are described with reference to the following figures:

FIG. 1 shows an embodiment of the first aspect of the present disclosure.

FIG. 2 shows a bottom side of the embodiment of FIG. 1.

FIG. 3 shows a an inside, namely the bypass element of the embodiment of FIG. 1 from a topside view.

FIG. 4 shows an overall topside view of the embodiment of FIG. 1.

FIG. 5 shows a further embodiment of the present disclosure.

FIG. 6 shows a further embodiment of the present disclosure.

FIG. 7 shows a topside view upon an exemplary bypass element according to the embodiments of FIGS. 5 and 6.

FIG. 8 shows a further embodiment of the present disclosure.

FIGS. 9 and 10 shows further embodiments of the present disclosure.

FIG. 11 shows an exemplary embodiment of the system according to the disclosure.

FIG. 12 shows an embodiment of the first aspect of the disclosure comprising sense terminals.

FIG. 13 shows a bottom side view of the embodiment of FIG. 12.

FIG. 14 shows a topside view of the bypass element according to the embodiment of FIG. 12.

FIG. 15 shows a further exemplary embodiment.

FIG. 16 shows at least part of the system comprising the embodiment of FIG. 15.

FIG. 17 is a cross-sectional view of a system, or at least part of the system according to the first aspect of disclosure.

FIGS. 18a and 18b show another embodiment of the disclosure.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. As well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line as described herein may be a single electrically conductive element or include at least two individual electrically conductive elements connected in series and/or parallel. Electrical lines may include metal and/or semiconductor material, and may be permanently electrically conductive (i.e., non-switchable). An electrical line may have an electrical resistivity that is independent from the direction of a current flowing through it. A semiconductor body as described herein may be made of (doped) semiconductor material and may be a semiconductor chip or be included in a semiconductor chip. A semiconductor body has electrically connected pads and includes at least one semiconductor element with electrodes. The pads are electrically connected to the electrodes which includes that the pads are the electrodes and vice versa.

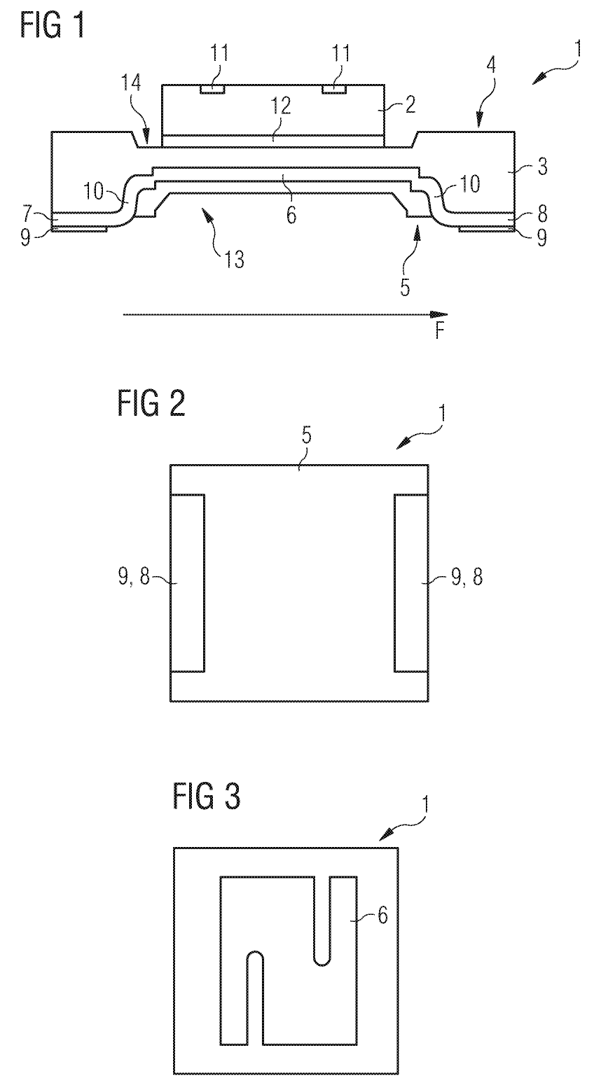

FIG. 1 shows sensor device 1 of the first aspect of the present disclosure. The sensor device 1 comprises a sense circuit 2 mounted onto an insulator body 3. The insulator body 3 comprises a first surface 4 and a second surface 5. A bypass element 6 is embedded in the insulator body 3. Further, the insulator body 3 comprises a first connector 7 and a second connector 8. Both the first connector 7 and the second connector 8 may comprise landing pads 9. The landing pads 9 are configured to enable attaching the sensor device 1 to a submount (not shown).

The first connector and the second connector 7, 8 are each electrically connected to the bypass element 6 by interconnect structures 10. The interconnect structures 10 may be embedded in the insulator body 3. The first connector and the second connector 7, 8 may be coplanar with the second surface of the insulator body or may protrude out of this second surface of the insulator body 3. The landing pads 9 are each attached to the first and second connectors 7, 8. The interconnect structures 10 are S-shaped electrical connectors and may be formed integrally with the first and second connector 7, 8, respectively.

The sense circuit 2 comprises at least one magnetic field sensitive element 11, which may be located at an upper surface of the sense circuit 2. The sense circuit is attached to the first surface 4 of the insulator body 3 by an adhesive 12.

The insulator body 3 comprises a first cavity 13 at the second surface 5. The first cavity 13 is a recess in the second surface 5 of the insulator body 3. The first cavity 13 spaces at least part of the second surface 5 away from the submount.

Further, the sense circuit 2 is arranged in a second cavity 14. That is, the sense circuit 2 is attached to the first surface of the insulator body 3 inside second cavity 14, namely at a bottom surface of the second cavity 14.

The sense circuit 2 is arranged such that a magnetic field induced at the bypass element 6 by a bypass current flowing through the bypass element 6 can be exactly measured, for example by differential sensing as will be explained below.

FIG. 2 shows a bottom side of the embodiment of FIG. 1. Particularly, FIG. 2 shows a bottom view of the second surface 5 of the insulator body 3. As can be seen, the first and second connectors 7, 8 which are covered by the landing pads 9 and are exposed from the insulator body 3. The first and second connectors 7, 8 are surface mount terminals carrying the landing pads 9 and are arranged spaced apart from one another in a direction of a main current flow F. The main current flow F is indicated in FIG. 1.

FIG. 3 shows an inside view, namely the bypass element 6 of the embodiment of FIG. 1 from a topside view. For differential magnetic field sensing, the bypass element 6 may be S-shaped. That is, for example, a substantially rectangular plate comprises two recesses so as to shape an S-shaped flow path for the bypass current.

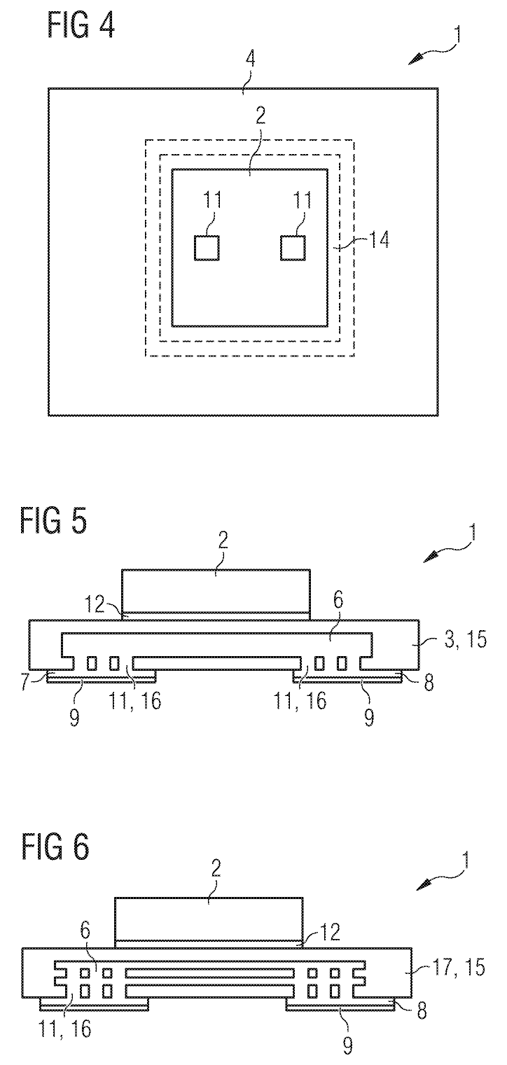

FIG. 4 shows an overall topside view of the embodiment of FIG. 1. The magnetic field sensitive elements 11 which are arranged at the sense circuit 2 are located overhead the recesses of the bypass element 6. The dashed lines indicate the edges, in this case a lower edge and an upper edge of the sidewalls of the second cavity 14.

FIG. 5 shows a further embodiment of the present disclosure. The insulator body 3 is a laminate 15, wherein the bypass element 6 is coupled to the first and second connectors 7, 8 by vias 16. The sense circuit 2 is arranged atop the laminate 15 and is not arranged in a cavity. The bypass element 6 is formed by a thick copper inlay of the laminate 15, suitable for high current densities. The insulator body 3, which is formed by the laminate 15 does not comprise any cavity at the second surface 5. Rather, the laminate 15 is spaced apart from the submount (not shown) by a thickness of the first and second connectors 7, 8. The first and second connectors 7, 8 are covered, that is, connected to the landing pads 9.

FIG. 6 shows a further embodiment of the present disclosure. The insulator body 3 is a multilayer substrate 17. The multilayer substrate 17 may also be a laminate 15. The bypass element 6 is a multilayer structure, that is a multilayer buried current carrier forming a multilayer structure together with layers of the multilayer substrate 17. The via structure 16 may be configured to route current signals to the different layers of the multilayer structure 17. Therefore, wires may be isolated towards single layers of the multilayer structure 17.

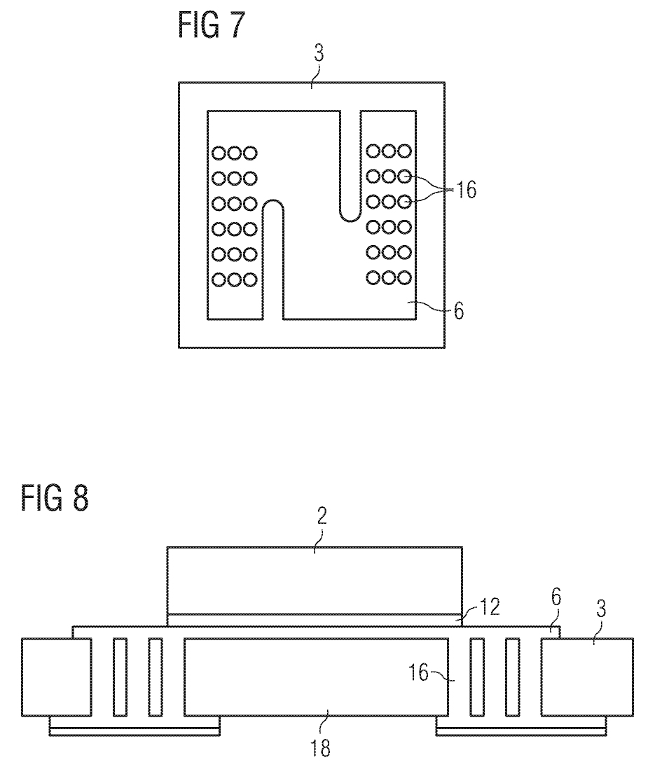

FIG. 7 shows a topside view upon an exemplary bypass element 6 according to the embodiments of FIGS. 5 and 6. The vias 16 are attached to the bypass element 6 and electrically connected thereto. The bypass element 6 is S-shaped. The vias 16 are arranged at edge portions of the S-shape.

FIG. 8 shows a further embodiment of the present disclosure. The bypass element 6 is located atop the insulator body and is contacted by vias 16. The sense circuit 2 is arranged directly atop the bypass element 6 and isolated towards the bypass element 6 by an insulating adhesive 12. Specifically, the insulator body 3 may be a glass carrier 18.

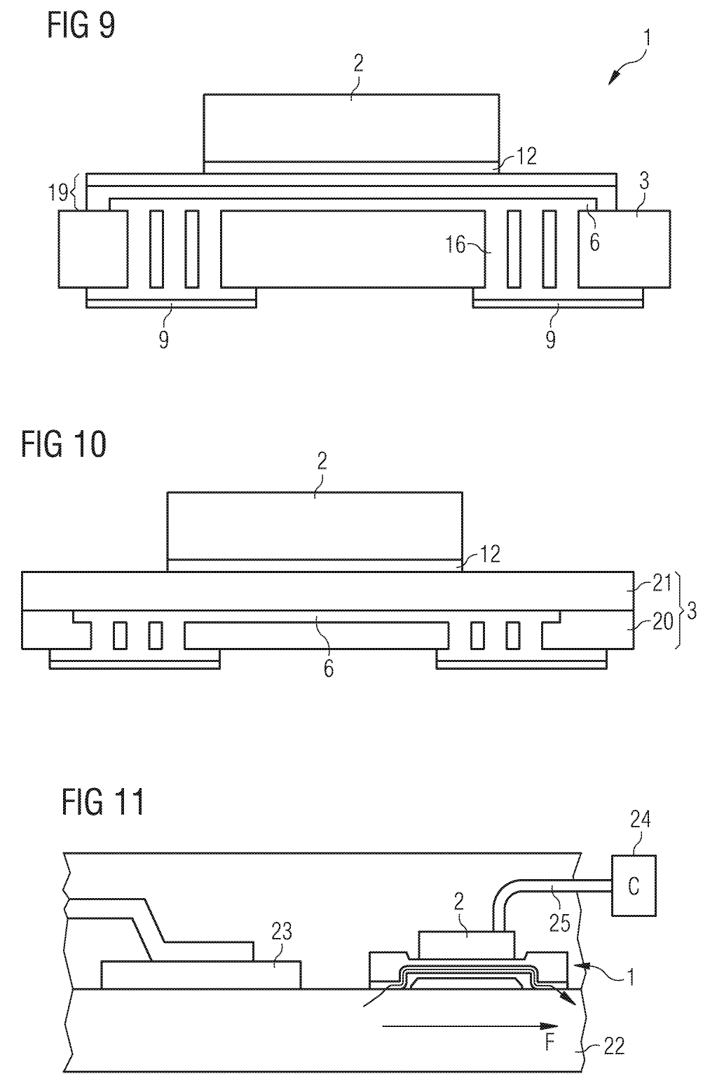

FIG. 9 shows a further variant of the embodiment of FIG. 8. The bypass element 6 is again arranged atop the insulator body 3. However, an insulating polyimide tape 19 is arranged between the insulating adhesive 12 and the bypass element 6.

FIG. 10 shows a further embodiment of the present disclosure. In this embodiment bypass element 6 is arranged in between directly bonded glass wafers. The insulator body 3 consists of a lower wafer 20 and an upper wafer 21. The bypass element 6 is fully embedded in the lower wafer 20, wherein a surface of the bypass element 6 is coplanar with an upper surface of the lower wafer 20. The upper wafer 21 is directly bonded onto the upper surface of the lower wafer 20. The upper wafer 21 forms an insulating layer towards the bypass element 6, which insulates the sense circuit 2 from the bypass element 6. The sense circuit 2 is attached to an upper surface of the upper wafer 21 by adhesive 12.

FIG. 11 shows an exemplary embodiment of the system according to the disclosure. The sensor device 1 is attached to a submount 22. Further, a semiconductor die 23 is attached to the submount 22. The semiconductor die 23 may be one of a Si-MOSFET, a SiC-MOSFET, an IGBT, a GaN-HEMT. For example, the submount 22 may be an AC portion of a half-bridge arrangement comprising several semiconductor devices 23. Generally, the submount 22 may be a leadframe. The system may further comprise a controller 24. The controller may be coupled to the sense circuit 2 of the sensor device 1 by the signal wires 25. As can be seen, the bypass current path through sensor device 1 is indicated by a thin arrow, and the main current path is indicated by arrow F. The bypass current path through the bypass element 6 substantially parallel to the main current path F.

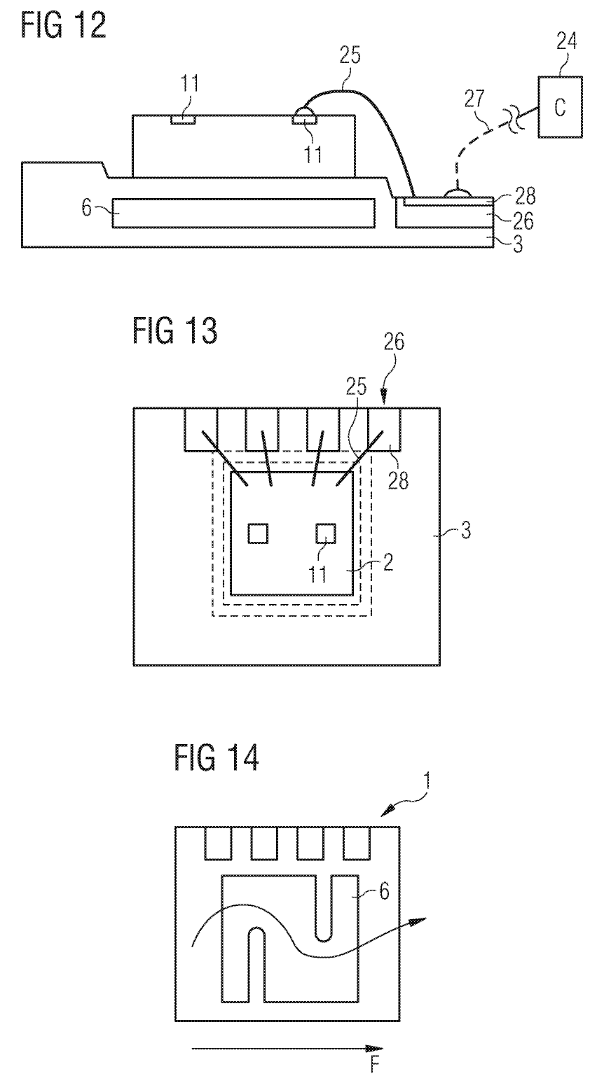

FIG. 12 shows an embodiment of the first aspect of the disclosure comprising sense terminals 26. The sense terminals 26 are fully embedded in the insulator body and configured to route signals from the signal wires 25 to pursuing wires 27. Signal wires 25 may be coupled to the magnetic field sensitive elements 11. Pursuing wires 27 may couple the sense terminals 26 to controller 24. The sense terminals 26 may comprise the metallization layer 28. The metallization layer 28 is configured to improve routing quality of incoming signals from the signal wires 25 to the pursuing wires 27 and to enable firm attachment of the pursuing wires 27.

FIG. 13 shows a bottom side view of the embodiment of FIG. 12. The sense terminals 26 are arranged at an outer edge of the insulator body 3 so as to be easily contacted by the pursuing wires 27 (not shown).

FIG. 14 shows a topside view of the bypass element 6 according to the embodiment of FIG. 12. The flow direction of the bypass current is indicated. Relative thereto, the flow direction of the main current path F is also indicated.

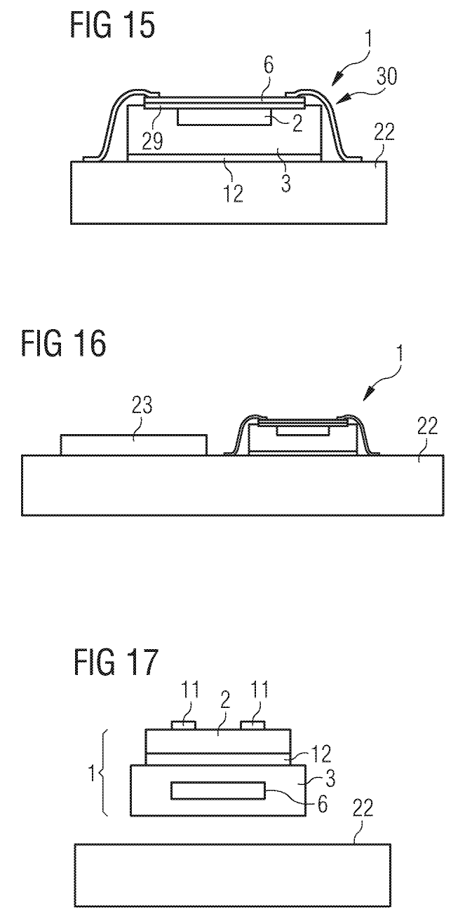

FIG. 15 shows a further exemplary embodiment. The sensor device 1 is an embedded wafer level ball grid array (eWLB) and arranged upside down. The insulator body 3 and the adhesive 12 form an insulator joint for attaching the sensor device 1 to the submount 22. The sense circuit 2 is fully embedded in the insulator body 3 at the topside of the insulator body 3, wherein the topside is arranged opposite to the adhesive 12. The sense circuit 2 may be coplanar with the top side of the insulator body 3. Alternatively, the sense circuit 2 may be covered with an isolating layer 29. Isolating layer 29 may be coupled with the topside of the insulator body 3. Bypass element 6 is arranged at the isolating layer 29. Bypass element 6 is contacted by ribbon bonds 30. Ribbon bonds 30 take the function of the interconnect structures 10 and the first and second connectors 7, 8. Ribbon bonds 30 electrically connect the bypass element 6 to the main current path of the submount 22.

FIG. 16 shows at least part of the system comprising the embodiment of the sensor device 1 of FIG. 15. The sensor device 1 is arranged at the submount 22. Semiconductor die 23 is arranged next to the sensor device 1 at the same surface of the submount 22.

FIG. 17 is a cross-sectional view of a system, or at least part of the system according to the first aspect of disclosure. The ratio between the bypass current and the main current depends on the ratio between a cross-section of the bypass element 6 to a cross-section of the submount 22 in the current flow direction. Hence, the ratio of the cross-section of the bypass element 6 vertical to the current flow direction, to a cross-section of the submount in the current flow direction F should be at least 0.08.

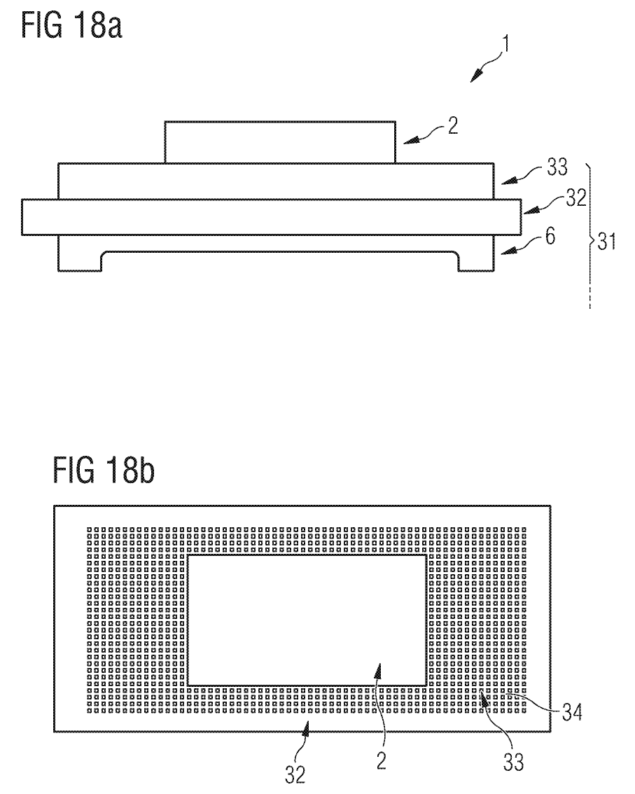

FIG. 18a is a cross-sectional view of a further embodiment of the sensor device 1 of the present disclosure. The insulator body 3 of the sensor device 1 is part of a direct copper bond (DCB) substrate 31. The insulator body 3 may also be part of an Active Metal Braze (AMB) substrate, or comprise a high temperature cofired ceramic (HTCC) or a low temperature cofired ceramic (LTCC). For example, the DCB substrate 31 may comprise a ceramic inlet 32 for insulation, which may form part of the insulator body 3. The ceramic inlet 32 has a first surface and a second surface opposite the first surface, wherein copper metallizations are attached to each of the first and second surfaces. The copper metallizations may be half etch metallizations and /or may be otherwise structured. A metallization at the lowermost surface may form the bypass element 6. A metallization 33 at a topside surface of the DCB substrate 31 may be arranged between the ceramic inlet 32 and the sense circuit 2.

However, embodiments without any metallization on the topside surface of the ceramic inlet 32 are also conceived. In this embodiment the sense circuit 3 is attached directly to the ceramic inlet 32, e.g. by way of glueing. In a further embodiment, the metallization 33 at the topside surface of the DCB substrate 31 may have a recess or cavity in which the sense circuit 3 is arranged, wherein the recess or cavity is free of metal, particularly wherein a surface of the cavity or recess equals the topside surface of the ceramic inlet 32.

The metallization 33 at the topside surface of the DCB substrate 31 may be structured, e.g. by etching or laser abrasion. For example, the metallization 33 at the topside surface of the DCB substrate 31 may be a mesh or a grid structure 34. The metallization 33 at the topside surface of the DCB substrate 31 may be applied as a paste, e.g. by ink jetting.

FIG. 18b is a topside view of the embodiment of FIG. 18a. The metallization 33 at the topside surface of the DCB substrate 31 is a grid structure 34, wherein the sense circuit 2 is attached to the grid structure 34. This may be achieved by way of soldering, diffusion soldering or glueing.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

### List of reference signs

1. Sensor device

2. sense circuit

3. insulator body

4. first surface of the insulator body

5. second surface of the insulator body

6. bypass element

7. first connector

8. second connector

9. landing pads

10. interconnect structures

11. magnetic field sensitive element

12. adhesive

13. first cavity

14. second cavity

15. laminate

16. vias

17. multilayer substrate

18. glass carrier

19. polyimide tape

20. lower wafer

21. upper wafer

22. submount

23. semiconductor die

24. controller

25. signal wires

26. sense terminals

27. pursuing wires

28. metallization layer

29. insulating layer

30. ribbon bonds

31. DCB/AMB/HTCC/LTCC

32. ceramic inlet

33. metallization at a topside surface of the DCB

34. mesh or grid structure

What is claimed is:

1. A sensor device configured to be attached to a submount, the submount forming a main current path, the sensor device comprising:
a first connector configured to connect to the main current path;
a second connector configured to connect to the main current path;
an electrical bypass element arranged between and coupled to the first connector and the second connector, the bypass element forming a bypass current path;
an insulator body receiving the bypass element; and
a sense circuit comprising at least one magnetic field sensitive element configured to sense a magnetic field induced by a bypass current through the bypass element.

2. The sensor device of claim 1, wherein the first connector is spaced apart from the second connector along the main current path, wherein the first and second connectors are surface mount terminals.

3. The sensor device of claim 1, wherein each connector of the first and second connectors comprises a landing pad.

4. The sensor device of claim 1, wherein at least one of the first and the second connector is connected to the bypass element by a respective interconnect structure, wherein the interconnect structure is a via.

5. The sensor device of claim 1, wherein the insulator body comprises a first main surface and a second main surface opposite the first main surface, wherein the second main surface faces the submount, wherein the second main surface comprises a first cavity between the first and second connectors, wherein a portion of the second main surface is spaced away from the submount.

6. The sensor device of claim 5, wherein the first main surface of the insulator body comprises a second cavity in which the sense circuit is arranged.

7. The sensor device of claim 1, wherein the insulator body is one of a mold body, a laminate body, and a glass carrier.

8. The sensor device of claim 1, wherein the insulator body comprises a plurality of sense terminals configured to receive and route sense signals from the at least one magnetic field sensitive element.

9. The sensor device of claim 1, wherein the first main surface of the insulator body comprises a cavity, wherein the sense circuit is attached to a bottom surface of the cavity by an adhesive.

10. The sensor device of claim 1, wherein the sensor device is mountable to a half bridge arrangement including two transistor devices, wherein the submount forms a phase node connecting the two transistor devices.

11. The sensor device of claim 1, wherein the sense circuit is embedded in the insulator body and covered by an insulating layer, wherein the bypass element is arranged atop the insulating layer.

12. The sensor device of claim 11, wherein the sensor device is attached to the submount, wherein the sense circuit is arranged at a surface of the sensor device facing away from the submount.

13. The sensor device of claim 11, wherein at least one of the first connector and the second connector are formed by a ribbon bond.

14. The sensor device of claim 1, wherein the at least one magnetic field sensitive element is one of a Hall-element or a magneto-resistive element.

15. A current sensing system, comprising:
the sensor device of claim 1;
the submount configured as a leadframe; and
a second mold body encapsulating at least part of the submount and the sensor device.

16. The current sensing system of claim 15, further comprising a controller configured to receive a sensing signal from the sensor device and to convert the sensing signal into a current value.

17. The current sensing system of claim 15, wherein an area ratio of a cross section of the bypass element vertical to a flow direction through the bypass element to a cross section of the submount vertical to a flow direction of a current flow direction in the submount is at least 0.08.

18. The current sensing system of claim 15, further comprising further circuitry configured to monitor a state of health and/or a state of operation of the current sensing system, wherein the further circuitry is arranged at the submount, wherein the further circuitry is configured for one or more of voltage sensing, humidity sensing, mechanical stress sensing, acceleration sensing, and temperature sensing.

19. A method for manufacturing a sensor device, the method comprising:
providing a first connector to connect to a main current path;
providing a second connector to connect to the main current path;
arranging a bypass element between the first connector and the second connector to form a bypass current path parallel to the main current path;
placing at least the bypass element in an insulator body; and
mounting a sense circuit at a first main surface of the insulator body, the sense circuit comprising at least one magnetic field sensitive element configured to sense a magnetic field induced by a bypass current through the bypass element.

20. The method of claim 19, further comprising embedding the first connector and the second connector in the insulator body.

21. The method of claim 19, further comprising:
coating the at least one magnetic field sensitive element with an insulating layer,
wherein placing at least the bypass element in the insulator body comprises covering the insulating layer with a current trace, the current trace forming the bypass element.

22. The method of claim 19, further comprising:
forming a frontside interconnect at the sensor device,
wherein forming the frontside interconnect comprises a plating step that includes plating, the plating comprising Ag and/or Ni.

23. The method of claim 19, wherein the mounting comprises:
before mounting the sense circuit to the insulator body, strip testing of an area of the insulator body where the sense circuit is to be mounted.

24. The method of claim 19, further comprising:
testing the sensor device.

25. The method of claim 24, wherein the testing comprises determining a breakdown voltage of the insulator body and/or calibrating the sense circuit.

26. The method of claim 19, further comprising:
mounting the sensor device to a submount, the submount forming the main current path.
